(19) United States
(12) Patent Application Publication
(10) Pub. No.: US 2024/0421787 A1
(43) Pub. Date: Dec. 19, 2024

(54) ELECTRONIC COMPARATOR CIRCUIT

(71) Applicant: Nordic Semiconductor ASA, Trondheim (NO)

(72) Inventor: Daniel MIONI, Trondheim (NO)

(73) Assignee: Nordic Semiconductor ASA, Trondheim (NO)

(21) Appl. No.: 18/744,376

(22) Filed: Jun. 14, 2024

(30) Foreign Application Priority Data
Jun. 19, 2023 (GB) 2309178.8

(51) Int. Cl. H03F 3/45; H03F 1/52

(52) U.S. Cl. CPC H03F 3/45179; H03F 1/523; H03F 2200/78

(57) ABSTRACT

An electronic comparator circuit, including an input portion, an output portion, a first portion, a second portion and a gain portion. The input portion includes a first input transistor and a second input transistor. In the first portion a first terminal of a first input transistor is connected between a first terminal of a third transistor and a second terminal of a fourth transistor, wherein the fourth transistor is connected in a diode configuration. The second portion includes a first terminal of a second input transistor connected between a first terminal of a fifth transistor and a second terminal of a sixth transistor, wherein the sixth transistor is connected in a diode configuration. The gain portion includes a gate of a seventh gain transistor cross-coupled to a gate of the fifth transistor. A gate of an eighth gain transistor is cross-coupled to a gate of the third transistor.

### CROSS REFERENCE TO RELATED APPLICATION

This application claims priority from Great Britain Application No. 2309178.8, filed Jun. 19, 2023, which application is incorporated herein by reference in its entirety.

### TECHNICAL FIELD

The present invention relates to an electronic comparator circuit arranged to compare two voltage inputs and to produce an output voltage dependent upon the relative values of the voltage inputs.

### BACKGROUND OF THE INVENTION

A comparator circuit compares two inputs, for example two input voltages, and produces an output which is dependent upon the relative values of the two inputs. The output may indicate both which is the larger of the two inputs, and the relative magnitude of the difference between the two inputs. Alternatively, the output may be binary and may indicate only which of the two inputs is larger.

The present invention seeks to provide an electronic comparator circuit that is capable of operating at low supply voltage, consuming a low current, and which is able to compare across a large common mode input range.

### SUMMARY OF THE INVENTION

From a first aspect, the invention provides an electronic comparator circuit, comprising:
an input portion, comprising a first input transistor, comprising a gate connected to a first voltage input, and a second input transistor, comprising a gate connected to a second voltage input;
an output portion, arranged to produce an output voltage dependent upon the relative values of the first voltage input and the second voltage input;
a first portion, comprising a third transistor, a fourth transistor, and a first current supply, connected in series, wherein a first terminal of the first input transistor is connected between a first terminal of the third transistor and a second terminal of the fourth transistor, such that the first terminal of the first input transistor and the first terminal of the third transistor are at the same voltage, wherein the fourth transistor is connected in a diode configuration;
a second portion, comprising a fifth transistor, a sixth transistor, and a second current supply, connected in series, wherein a first terminal of the second input transistor is connected between a first terminal of the fifth transistor and a second terminal of the sixth transistor, such that the first terminal of the second input transistor and the first terminal of the fifth transistor are at the same voltage, wherein the sixth transistor is connected in a diode configuration; and
a gain portion, comprising a seventh gain transistor and an eighth gain transistor, wherein a gate of the seventh gain transistor is cross-coupled to a gate of the fifth transistor, a gate of the eighth gain transistor is cross-coupled to a gate of the third transistor, the transconductance of the seventh gain transistor is lower than the transconductance of the third transistor and the transconductance of the eighth gain transistor is lower than the transconductance of the fifth transistor.

Thus it will be seen that, in accordance with the invention, by connecting the first terminals of the first input transistor and the second input transistor in the stated manner the voltage range available over the input transistors is kept large. By arranging the gain transistors in the stated manner, with their transconductances being higher, respectively, than those of the third and fifth transistors, the gain on the output voltage is increased. The overall effect of these features is to provide an electronic comparator circuit with a high common mode input range (CMIR) (e.g. approximately 0.6 V) capable of operating at low power (e.g. of consuming only nA, for example 50 nA total of current), and with a low supply voltage (e.g. down to 0.6 V).

As stated above, the arrangement within the first portion and the second portion of the first terminal of the input transistors is such that the available voltage drop over these input transistors is large, since the voltage drop over the third and fifth transistors is low. For example, the third transistor and/or the fifth transistor may be arranged so that the voltage drop across the third transistor and/or the fifth transistor is approximately 50 mV (i.e. 50 mV less than a positive supply voltage of the electronic comparator circuit). This allows the comparator circuit to operate even where the supply voltage is low.

It will be appreciated that where transistors are referred to numerically (e.g. the seventh gain transistor) this number is used only for reference purposes for each transistor, so that each may be referenced clearly, but does not give an indication of a total number of transistors either of that type of transistor or overall. For example, the reference to “the seventh gain transistor” does not indicate that a total of seven gain transistors are present, nor that a total of seven transistors need be included.

It will be appreciated that the transistors are controlled by voltages applied to their gates, and that therefore each transistor is a field effect transistor.

It will be appreciated that the first and second terminals of the transistor referred to are the non-gate terminals of the transistor, i.e. the source and drain terminals. The first terminals may be drain terminals and the second terminals may be source terminals. Alternatively, the first terminals may be source terminals and the second terminals may be drain terminals.

One or more (or all) of the following transistors may be PMOS transistors: the third transistor, the fourth transistor, the fifth transistor, the sixth transistor, the seventh gain transistor, the eighth gain transistor.

In some embodiments, a second terminal (e.g. a source terminal) of one or more of the third transistor, the seventh gain transistor, the eighth gain transistor and the fifth transistor may be connected to a positive supply voltage of the electronic comparator circuit (sometimes referred to as Vdd).

The first input transistor and the second input transistor may both be NMOS transistors.

Alternatively, all those transistors referred to herein as PMOS may be NMOS, and those referred to as NMOS may be PMOS.

In some embodiments, the third transistor and the fourth transistor have the same aspect ratio, i.e. they are the same size. Thus, in some embodiments, the third transistor and the fourth transistor have (approximately) the same threshold voltage. This helps to ensure that the third transistor operates in the triode region, and thereby helps to ensure that the voltage range available over the input transistors is kept large. Similarly, in some embodiments, the fifth transistor and the sixth transistor have the same aspect ratio, i.e. they are the same size. Thus, in some embodiments, the fifth transistor and the sixth transistor have (approximately) the same threshold voltage. In some embodiments, the third transistor and the fourth transistor are of the same type. Similarly, in some embodiments, the fifth transistor and the sixth transistor are of the same type, e.g. both JFET or MOSFET, or more specifically both the same type of CMOS device e.g. both thin oxide, thick oxide, low Vth, high Vth, etc.

In some embodiments, the first input transistor and the second input transistor are arranged in a differential configuration. In some embodiments, the electronic comparator circuit (e.g. the input portion) further comprises a third current supply. The third current supply may be connected to the first input transistor and/or the second input transistor. For example, the first input transistor and the second input transistor may be connected in parallel to the third current supply. The third current supply may supply a current of approximately 30 nA.

In some embodiments, the first current supply and the second current supply approximately the same current. For example, the first current supply and the second current supply may supply a current of approximately 7.5 nA.

The transconductances of the first input transistor and the second input transistor may be equal (i.e. for the same gate voltage). The transconductances of the third transistor and the fifth transistor may be equal. The transconductances of the fourth transistor and the sixth transistor may be equal. The transconductances of the seventh gain transistor and the eighth gain transistor may be equal.

As stated above, the arrangement of the seventh and eighth gain transistors being cross-coupled, and each having transconductances higher than the transconductances of the third and fifth transistors, respectively, (i.e. having a transconductance ratio greater than one), provides gain at the voltage output. For improved gain, it is preferable that the transconductance of the seventh gain transistor is close to the transconductance of the third transistor. Similarly, it is preferable that the transconductance of the eighth gain transistor is close to the transconductance of the fifth transistor. The closer the ratio is to unity, the higher the gain. Higher gain improves operation of the electronic comparator circuit and allows the electronic comparator circuit to compare small voltage differences.

In some embodiments, a gate of the third transistor and a gate the fourth transistor are coupled together. Thus, in some embodiments, the gate of the eighth gain transistor is coupled (i.e. cross-coupled) to the gate of the fourth transistor.

In some embodiments, a gate of the fifth transistor and a gate of the sixth transistor are coupled together. Thus, in some embodiments, the gate of the seventh gain transistor is coupled (i.e. cross-coupled) to the gate of the sixth transistor.

In some embodiments, a first terminal (e.g. a drain terminal) of the seventh gain transistor is coupled to the first terminal of the first input transistor. It will be appreciated that since the first terminal of the first input transistor is connected between the first terminal of the third transistor and the second terminal of the fourth transistor, the first terminal of the seventh gain transistor may be connected between the first terminal of the third transistor and the second terminal of the fourth transistor.

In some embodiments, a first terminal (e.g. a drain terminal) of the eighth gain transistor is coupled to the first terminal of the second input transistor. It will be appreciated that since the first terminal of the second input transistor is connected between the first terminal of the fifth transistor and the second terminal of the sixth transistor, the first terminal of the eighth gain transistor may be connected between the first terminal of the fifth transistor and the second terminal of the sixth transistor.

The electronic comparator circuit may further comprise at least one mirror portion, arranged to mirror the current flowing through the third transistor and/or the fifth transistor (i.e. to mirror it onto the output portion).

In some embodiments, the electronic comparator circuit comprises a first mirror portion, arranged to mirror current from the fifth transistor to the output portion. In some embodiments, the electronic comparator circuit (e.g. the first mirror portion) further comprises a (ninth) mirror transistor. A gate of the fifth transistor may be connected to a gate of the (ninth) mirror transistor. The (ninth) mirror transistor may form part of the output portion. Thus, the (ninth) mirror transistor and the fifth transistor may together form a mirror portion, arranged to mirror the current flowing through the fifth transistor.

In some embodiments, the electronic comparator circuit comprises a second mirror portion, arranged to mirror current from the third transistor to the output portion. In some embodiments, the electronic comparator circuit (e.g. the second mirror portion) further comprises a (tenth) mirror transistor. A gate of the third transistor may be connected to a gate of the (tenth) mirror transistor. As set out above, in some embodiments, the gate of the third transistor and the gate the fourth transistor are coupled together. Therefore, in some embodiments, the gate of the (tenth) mirror transistor is coupled to the gate of the fourth transistor (i.e. to the diode connected transistor). Thus, the (tenth) mirror transistor and the third transistor may together form a mirror portion, arranged to mirror the current flowing through the third transistor.

The ninth and tenth mirror transistors may both be PMOS transistors, or alternatively, may both be NMOS transistors. A second terminal (e.g. a source terminal) of the ninth mirror transistor and/or the tenth mirror transistor may be connected to the positive supply voltage.

In some embodiments, the electronic comparator circuit (e.g. the second mirror portion) further comprises an (eleventh) mirror transistor, connected in a diode configuration, wherein a first terminal of the tenth mirror transistor is connected to a first terminal of the eleventh mirror transistor. As set out above, the first terminals may both be drain terminals or alternatively may both be source terminals.

In some embodiments, the electronic comparator circuit (e.g. the second mirror portion) further comprises a (twelfth) mirror transistor, wherein a gate of the twelfth mirror transistor is connected to a gate of the eleventh mirror transistor. The twelfth mirror transistor may form part of the output portion.

The eleventh and twelfth mirror transistors may both be NMOS transistors, or alternatively, may both be PMOS transistors. A second terminal (e.g. a source terminal) of the ninth mirror transistor and/or the tenth mirror transistor may be connected to a negative supply voltage of the electronic comparator circuit (sometimes referred to as Vss).

The voltage output portion may comprise a high impedance node. This helps to provide gain for the voltage output. In some embodiments, a first terminal (e.g. a drain terminal) of the ninth mirror transistor is connected to a first terminal (e.g. drain terminal) of the twelfth mirror transistor. The output portion may comprise a voltage output terminal, located between the first terminal of the ninth mirror transistor and the first terminal of the twelfth mirror transistor.

Although the third transistor, fourth transistor, seventh gain transistor, and eighth gain transistor (and also the ninth and tenth mirror transistors) are each referred to as “a transistor”, it will be appreciated that each of these transistors (and further optionally any of the other disclosed transistors) could be provided by more than one transistor connected together in a suitable arrangement to provide the functionality of a single transistors. For example, each such transistor may be provided by two (or more) transistors connected in series (i.e. source-to-drain or drain-to-source), with their outer terminals (i.e. the terminals that aren't connected to the other terminal of the pair) connected in the manner described above.

In some embodiments, the electronic comparator circuit comprises at least one (preferably two) (e.g. thirteenth and fourteenth) hysteresis transistors, wherein the at least one hysteresis transistor is arranged to provide hysteresis of the output portion. In some embodiments, the electronic comparator circuit comprises at least one (optionally a first and a second) inverter, arranged to invert the output voltage (that is output by the output portion), and to supply this inverted output voltage to (a gate of) one of the hysteresis transistors as a control signal.

In some embodiments, the third transistor comprises (i.e. is provided by) a pair of series-connected transistors, wherein a first terminal (e.g. drain terminal) of the thirteenth hysteresis transistor is connected between the pair of series-connected transistors. In some embodiments, the electronic comparator circuit comprises a first inverter, arranged to invert the output voltage, and to apply the resulting signal to a gate of the thirteenth hysteresis transistor. In some embodiments, the transconductance of the thirteenth hysteresis transistor is higher than the transconductance of the third transistor. The first inverter may be arranged to convert an analog signal at the voltage output to a digital signal.

In some embodiments, the fifth transistor comprises (i.e. is provided by) a pair of series-connected transistors, wherein a first terminal (e.g. drain terminal) of the fourteenth hysteresis transistor is connected between the pair of series-connected transistors. In some embodiments, the electronic comparator circuit comprises a second inverter, arranged to invert the resulting signal produced by the first inverter, and to apply the further inverted signal to a gate of the fourteenth hysteresis transistor. In some embodiments, the transconductance of the fourteenth hysteresis transistor is higher than the transconductance of the fifth transistor.

Features of any aspect or embodiment described herein may, wherever appropriate, be applied to any other aspect or embodiment described herein. Where reference is made to different embodiments or sets of embodiments, it should be understood that these are not necessarily distinct but may overlap. It will furthermore be understood that references made to a method comprising a step correspondingly extend to a module “configured to” carry out a step, and vice versa.

### BRIEF DESCRIPTION OF THE DRAWINGS

An embodiment of the invention will now be described, by way of example only, with reference to the accompanying drawings, in which:

FIG. 1 is a circuit diagram showing an operational transconductance amplifier according to the prior art;

FIG. 2 is a circuit diagram showing an electronic comparator circuit according to a first embodiment of the present invention; and

FIG. 3 is a circuit diagram showing an electronic comparator circuit according to a second embodiment of the present invention.

### DETAILED DESCRIPTION

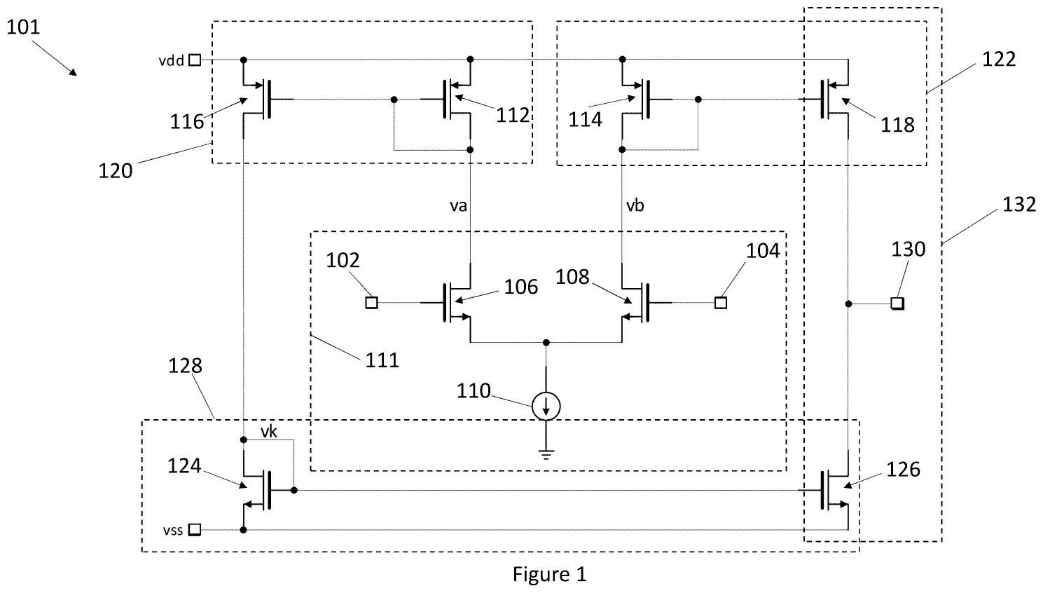

For explanatory purposes, a known arrangement of an operational transconductance amplifier will be described with reference to FIG. 1.

The OTA circuit 101 includes two voltage inputs Vᵢ− 102 and Vᵢ+ 104 which are to be compared. One of these voltage inputs 102, 104 is inverted relative to the other. Each voltage input 102, 104 is connected to the gate of a respective NMOS (metal-oxide-semiconductor) field effect transistor 106, 108, which may be referred to as input transistors 106, 108. The source of each of these transistors is connected to a current supply 110. The two input transistors 106, 108 have the same transconductances as each other.

It will be appreciated that where the voltage inputs 102, 104 are perfectly balanced, equal current will flow through each of the transistors 106, 108 from the current supply 110. However, where the voltage at one of the voltage inputs 102, 104 increases, relative to the other voltage input 104, 102, correspondingly the current flowing through the corresponding transistor 106, 108, increases, since its transconductance is increased due to its increased gate voltage, and therefore the current flowing through the other transistor decreases (since the current between both transistors must be equal to the current supplied by the current supply 110). This transistor arrangement 111 is referred to as a differential configuration.

The drain of each input transistor 106, 108 respectively is connected to the drain of a respective PMOS transistor 112, 114. These transistors 112, 114, referred to as diode transistors, are each connected in an arrangement known as a diode arrangement. The two diode transistors 112, 114 have the same transconductances as each other. In the diode arrangement, the drain of each transistor 112, 114 is connected to the gate of that same transistor. As a result of this connection, the transistor operates as a diode.

The voltage drop over the diode transistors 112, 114 will generally be large, leaving only a small voltage range available for the input transistors. In other words, the operating range of the input transistors 106, 108 will be limited by the minimum voltages across the diode transistors 112, 114.

As a result, where the voltage difference between the positive supply voltage Vdd and the negative supply voltage Vss is close to Vₜₕ of the diode transistors 112, 114, this leaves a very small voltage range Va, Vb over each of the input transistors 106, 108 (i.e. a small headroom). This means that the input transistors 106, 108 are likely to be operating in the “triode” region, in which the relationship between the input voltage and the output voltage is linear. A transistor is operating in the triode region when the condition is met that V_{gs}>V_{ds}−Vₜₕ, where V_{ds} is the voltage between the drain and source terminals, V_{gs} is the voltage between the gate and source terminals, and Vₜₕ is the threshold voltage of the transistor, which is the minimum gate-to-source voltage that is needed to create a conducting path between the source and drain terminals, i.e., the gate-to-source voltage at which the transistor turns “ON”.

Where the input voltages 102, 104 are close to Vdd level the voltage drop across Vds for the input transistor is almost certainly smaller than Vgs, because the voltage drop must always be smaller than Vdd for the circuit, and there is a large voltage drop over the diode transistors, and so it will be operating in the triode region. This decreases the gain in the input transistors 106, 108 considerably. This increases the systematic offset of the OTA considerably, meaning that the measured voltage difference is offset (i.e. shifted) relative to the true voltage difference value.

In the arrangement shown in FIG. 1, V_{ds} for the input transistors 106, 108, is equal to:

V_{dd}−Vgs_{112,114}

This condition defines the maximum common mode input range over which the OTA circuit 101 is able to operate:

$${V}_{max} \leq {V}_{dd} - {Vgs}_{112 , 114} + {Vth}_{106 , 108}$$

Therefore, the lower the voltage drop on the diode transistors 112, 114, the greater the common mode input range of the comparator 101.

The gate of each of the diode transistors 112, 114 is further connected to the gate of an associated (PMOS) transistor 116, 118. Each of these connected pairs of transistors forms a current mirror 120, 122, since the voltage applied to the gate of mirror transistor 116, 118 will be equal to the voltage applied to the gate of its associated diode transistor 112, 114.

The diode transistor 114 seen on the right-hand side of the OTA circuit 101 (where left and right refer to the directions relative to the view shown in FIG. 1) mirrors onto its associated mirror transistor 118 (which may be referred to as an output transistor 118), which is itself part of an output stage 132 of the OTA circuit 101, discussed later.

The transistor 116 of the other mirror circuit 120, seen on the left-hand side of the OTA 101, has its drain connected to another mirror circuit 128, which includes another diode connected transistor 124, and another mirror transistor 126, which has its gate connected to the gate of the diode transistor 124. This mirrors the current from the transistor 116 onto the transistor 126. The diode transistors 112, 124, and the mirror transistor 118, may all have the same transconductances. Even where they do the voltages vk (of the lower diode transistor) and va (of the upper diode transistor 112) may not be equal, since vk is referred to Vss, the negative supply voltage, while va is referred to Vdd, the positive supply voltage. In the illustrated example, the current mirror circuits 120, 122 and 128 are unit gain, and therefore provide no current amplification.

Thus, when the voltage value at the voltage input 106 on the left-hand side of the OTA circuit 101 increases, this increases the transconductance of the left-hand transistor 106 and therefore increases the current flowing through this left-hand branch. This increase in transconductance decreases the voltage drop across that transistor 106, causing the voltage Va to decrease. This increase in current is mirrored onto the lower output transistor 126, as explained above, by its transconductance being increased. Correspondingly, since greater current is flowing through the left-hand branch of the OTA 101, less current is flowing through the right-hand branch (since together the currents in the two branches sum to that of the current supply 110). Therefore the current flowing through the upper output transistor 118 is decreased and Vb increases. The result of this is that the voltage at a voltage output 130, located between the two output transistors 118, 126, is pulled down, towards the negative supply voltage Vss. Conversely, where the voltage at the right-hand voltage input 108 increases, the current flowing through the upper output transistor 118 increases as a result, and the current through the lower output transistor 126 decreases, raising the voltage at the voltage output 130 towards the positive supply voltage Vdd. The output voltage at voltage output 130 therefore varies depending on which input voltage is higher, and by how much. It will be appreciated that this output voltage 130 is analog.

When connecting two transistor drains in parallel they form a high resistance node 130. This high resistance means that any small change in current at the node will result in a very large change in voltage at the node 130 (i.e. there is a steep gradient to the relationship). Therefore, a change in current will cause the voltage at the output 130 to very quickly reach either the minimum voltage of the circuit, Vss, or the maximum voltage of the circuit Vdd. This is referred to as “tripping” the voltage output. It allows the analog output 130 to output a signal which may effectively be considered as binary since it almost always has one of two values, either Vss or Vdd.

However, there are drawbacks to this known arrangement of FIG. 1. Firstly, since the voltage drop across the diode transistors 112, 114 must be at least equal to the threshold voltage of each of the diode transistors, this leaves a very small voltage range Va, Vb over each of the input transistors 106, 108, meaning that they are likely to be operating in the “triode” region if the input voltages 102, 104 are voltages close to the Vdd level. This is because if Vgs of the input transistor is close to Vdd then the voltage drop across Vds for the input transistor must always be smaller than Vgs, because the voltage drop must always be smaller than Vdd for the circuit, and so it will be operating in the triode region. Furthermore, the only voltage gain is made in the output stage 132, and therefore the OTA circuit 101 is unable to accurately detect small differences in voltage between the voltage inputs.

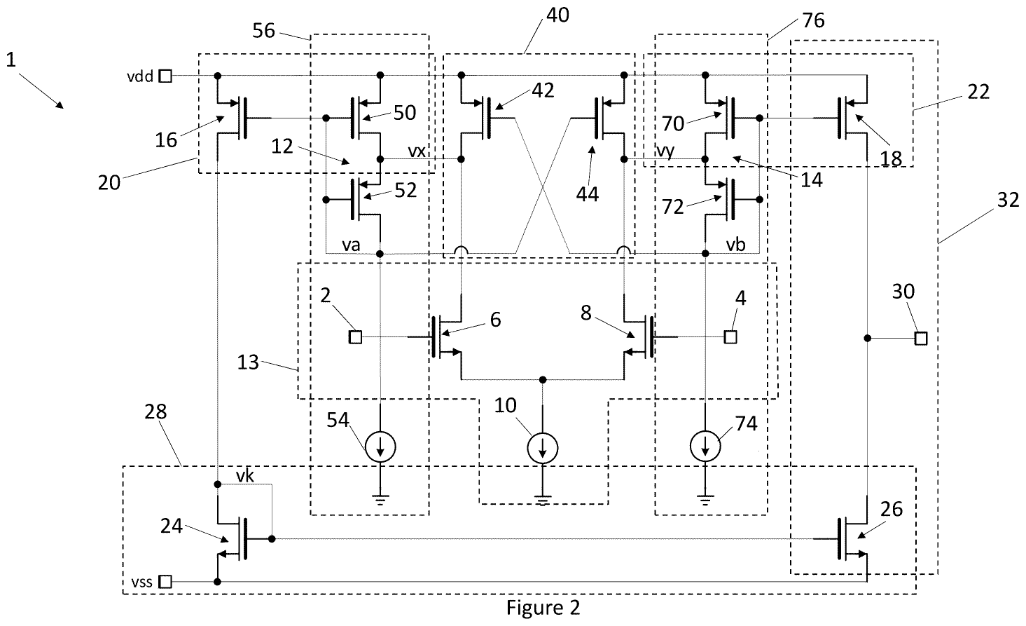

FIG. 2 shows an electronic comparator circuit 1 according to a first embodiment of the present invention, which aims to address at least some of these shortcomings.

The electronic comparator circuit 1 includes two voltage inputs Vᵢ− 2 and Vᵢ₊4 which are to be compared. Each voltage input 2, 4 is connected to the gate of a respective NMOS (metal-oxide-semiconductor) field effect transistor 6, 8, which may be referred to as input transistors 6, 8. The source of each of these transistors is connected to a first current supply 10. The first current supply 10 may, for example, supply a current of approximately 30 nA. The input transistors 6, 8 have the same transconductances. This transistor arrangement 13 is referred to as a differential configuration.

The electronic comparator circuit 1 further includes a pair of transistors 42, 44, referred to as gain transistors, which together provide a gain boost, and are therefore referred to together as a gain portion 40 of the circuit 1, as discussed further below.

The drain of each input transistor 6, is connected to the drain of a PMOS transistor 50, referred to as the upper transistor 50. The source of this transistor 50 is connected to the positive supply voltage Vdd. As indicated in FIG. 2, the drain of this upper transistor 50, and therefore also the drain of input transistor 6, are at voltage Vx. The drain of this upper transistor 50 is connected to the source of a further PMOS transistor 52, referred to as a diode transistor, which is arranged in a diode connection, keeping the voltage at both its drain and its gate at Va, and also keeping the gate voltage of transistor 50 at Va. The upper transistor 50, the diode transistor 52, and a current supply (54) (which may be referred to herein as a second current supply, for convenience, but may elsewhere be referred to as a first, or third etc. current supply), together provide a drain-voltage setting portion 56. Such an arrangement, including transistors in series such that one is always operating in the triode region, and the other is biased by a current to operate in saturation, is sometimes referred to as a “self-cascode MOS”.

Thus, in place of the single diode transistor 112 of the prior art example of FIG. 1, there is provided a pair of transistors 12, including the upper transistor 50 and the diode transistor 52, as described above. Similarly, in place of the single diode transistor 114, there is provided a pair of transistors 14, including a second upper transistor 70 and a second diode transistor 72.

The current flowing through the upper transistor 50 is equal to approximately:

$$1 / 2 of IDC 1 + IDC 2 - {I}_{42}$$

where IDC1 is the current supplied by first current supply 10, IDC2 is the current supplied by the second current source 54 that is connected in series with the upper transistor 50 and the diode transistor 52, and 142 is the current flowing through the gain transistor 42 which “steals” some current from the upper transistor 50 branch, as described below.

When the voltage at left-hand voltage input 2 increases (i.e. to more than the input voltage at right-hand input 4), the current flowing through input transistor 6 increases, as it draws greater current from the first current supply 10, and therefore the current through the other input transistor 8 decreases. This therefore causes the current flowing through the upper transistor 50 to increase. Since upper transistor 50 is operating in the triode region, as the current in the upper transistor 50 increases, the voltage drop across it increases and therefore the voltage vx decreases. Since the diode transistor 52 is biased with a fixed current, from the second current supply 54, V_{gs} and V_{ds} for that diode transistor 52 are fixed, and therefore any voltage change in vx will be seen correspondingly in va, since the difference between va and vx is a fixed voltage drop defined over the diode transistor 52.

The current flowing through the upper transistor 50 is mirrored through a first current mirror circuit 20, and a second current mirror circuit 28, which operate in the same way as the current mirrors 120, 128 described above in relation to FIG. 1. An output voltage is produced at voltage output 30, based on the currents being mirrored onto respective output transistors 18, 26, of an output portion 32, in the same was as described above with reference to FIG. 1.

A difference with respect to the prior art example of FIG. 1 is that in the embodiment of FIG. 2, the resultant voltage applied to the drain of the input transistor 6 is equal to Vx, the drain voltage of the upper transistor 50, rather than Va, the drain voltage of the diode transistor. A diode connected transistor, such as diode transistor 52, will generally always operate at saturation, and therefore the voltage drop across that transistor will always be at least the threshold voltage of that diode transistor, and therefore relatively large.

As discussed above, the upper transistor 50 and the diode transistor 52 are connected in a “self-cascode MOS” structure. In this arrangement, both devices share the same gate voltage, V_{g}, whilst the source voltage (Vₛ) of the diode transistor 52 is equal to the drain voltage (V_{d}) of the upper transistor 50. Thus, V_{gs} for the diode transistor 52 is equal to V_{gd} for the upper transistor 50.

By selecting the upper transistor 50 and the diode transistor 52 to have the same size (i.e. the same aspect ratio), this means that for the upper transistor 50:

$${V}_{sg} = {V}_{dd} - va$$

$${V}_{sd} = {V}_{dd} - vx$$

and for the diode transistor 52:

$${V}_{sg} = vx - va$$

As already explained, diode transistor 52 is always operating in saturation since it is diode connected (V_{sg}=V_{sd}). It is far from the transition V_{sd}=V_{sg}−Vₜₕ

For the upper transistor 50, the transition point between saturation and triode operation is:

V_{sd}=V_{sg}−Vₜₕ (i.e. if V_{sd}<V_{sg}−Vₜₕ, the device is operating in triode)

Substituting in the equations set out above for V_{sg} and V_{sd} of the upper transistor 50, this gives:

$${V}_{dd} - vx < {V}_{dd} - va - {V}_{th}$$

giving:

$$vx - va > {V}_{th}$$

so:

V_{gs}(diode transistor 52)>Vₜₙ(upper transistor 50)

Thus, if it is ensured that V_{gs} for the diode transistor 52 is larger than the threshold voltage for the upper transistor 50, then the upper transistor 50 will be operating in the triode region.

If the upper transistor 50 and the diode transistor 52 are the same size and the same type, they will have (approximately) the same threshold voltage, and since V_{gs} for the diode transistor 52 will always be above the threshold voltage for the diode transistor 52, it will therefore always be over the threshold voltage for the upper transistor 50, ensuring that the upper transistor 50 is in triode operation.

Since the upper transistor 50 is operating in the triode region, the voltage drop Vx across the upper transistor will be relatively small. Thus, the voltage Vx will be close to the positive supply voltage Vdd. For example, the voltage Vx may be up to 50 mV less than the positive supply voltage Vdd. This leaves a larger voltage range available across the input transistor 6 (as compared to the prior art arrangement described above with reference to FIG. 1), allowing it to operate in the saturation region, even when the input voltages 2, 4 are close to the Vdd level. The difference between Vdd and Va, the diode transistor 52 drain voltage, may be up to approximately 1V.

In order for the input transistors 6, 8 to be operating in the saturation region, the following condition must hold for each of those transistors 6, 8:

$${V}_{gs} < {V}_{ds} + {V}_{th}$$

and in the arrangement shown in FIG. 2, V_{ds} for transistor 6, 8, is equal to:

$${V}_{dd} - ( {Rds}_{50 , 70} \times ( 1 / 2 IDC 1 ) )$$

where Rds_{50,70} is the resistance between the drain and source of the upper transistors 50, 70, respectively, and IDC1 is the current supplied by the current source 10. This condition defines the maximum common mode input range over which the OTA circuit 1 is able to operate:

$${V}_{max} \leq {V}_{dd} - ( {Rds}_{50 , 70} \times ( 1 / 2 IDC 1 ) ) + {Vth}_{6 , 8}$$

Therefore, the lower the voltage drop on the diode transistors 50, 70, the greater the common mode input range of the comparator 1.

The operation of a second drain-voltage setting portion 76, and a third mirror circuit 22, of the right-hand side of the electronic comparator circuit 1 will not be explained separately, since they operate in the same manner as those on the left-hand side, which are explained above. The second drain-voltage setting portion 76 similarly comprises an upper transistor 70, a diode transistor 72, and a third current supply 74. The upper transistor 70 also forms part of the third mirror circuit 22, together with an output transistor 18. The third current supply 74 supplies the same amount of current as the second current supply 54. The second current supply 54 and the third current supply 74 may supply a current of approximately 7.5 nA.

The gain transistor 42 is connected in series with the left-hand-input transistor 6. The gate of the gain transistor 42 is connected to the gates of the upper transistor 70 and the diode transistor 72 of the right-hand side of the circuit (i.e. of the opposite branch of the circuit 1). Similarly the gate of right-hand gain transistor 44 is connected to the gates of the upper transistor 50 and the diode transistor 52 of the left-hand side of the circuit (i.e. of the opposite branch of the circuit 1). As a result, when the current increases on the left-hand branch, i.e. flowing through the left-hand input transistor 6, the voltage Va of the gate of the diode transistor 52 decreases (the voltage drop increases), and therefore also on the gate of right-hand gain transistor 44 decreases. The gain transistor 44 is a PMOS transistor, referenced to voltage Vdd, and therefore this “decrease” in the applied gate voltage increases V_{gs} for this gain transistor 44, since the applied gate voltage is further from Vdd. Therefore, as a result of this, the portion of the current from the third current supply 74 that flows through the gain transistor 44 increases, and therefore current flowing through upper transistor 70, and therefore through output transistor 18 (because it is mirroring the upper transistor 70), decreases. Conversely, the gate voltage Vb of the right-hand diode transistor 72 is increased (the voltage drop is decreased) by the drop in current through input transistor 8. This causes left-hand gain transistor 42 to become less conductive, i.e., to start closing, so that greater current flows through the left-hand upper transistor 50, thereby increasing the current through output transistor 26. Thus, by cross-coupling the gates of each gain transistor 42, 44 to the gates of the upper and diode transistors 50, 52, 70, 72 of the opposite branch, changes in current are emphasised such as to further increase the gain of the comparator 1.

The transconductances of the gain transistors 42, 44 (which are the same as each other) are lower than the transconductances of the two upper transistors 50, 70 (i.e. each gain transistor has a lower transconductance than the corresponding upper transistor on the same side of the circuit 1). This has the effect that the gain transistors 42, 44 “steal” a small amount of current from each of the second and third current supplies respectively, rather than taking a significant portion of the current (when conducting) so that it emphasises the existing changes, rather than effectively counteracting the changes (causing hysteresis). In other words, keeping the transconductances of the two upper transistors 50,70 higher than that of the gain transistors 42, 44 will provide a boost in the circuit voltage gain, as can be seen in the equation below. If the transconductances of the two upper transistors 50,70 are lower than the transconductances of the gain transistors 42, 44, then the circuit would perform hysteresis, which is not the intention for the gain portion 40. For example, a ratio of between gain transistor 42, 44:upper transistor 50, 70 may be chosen to give a gain of approximately 20 times.

The gain of the circuit 1 of FIG. 2 can be calculated from the equation shown below:

$$G = \frac{{gm}_{6 , 8}}{( {gm}_{70 , 50} - {gm}_{44 , 42} )} \times \frac{( {gm}_{18} + {gm}_{26} )}{( {gds}_{26} + {gds}_{18} )}$$

where gm_{6,8} represents the transconductance of the input transistors 6 and 8, and the other gm symbols similarly correspond to the transistors having the associated reference numerals. The transconductance of a transistor is the ratio, for an active device, of the change in current at the output terminal to the change in voltage at the input terminal.

gds₂₆ is the drain conductance of the lower output transistor 26, whilst gds₁₈ is the drain conductance of the upper output transistor 18. The drain conductance is effectively the inverse of the output resistance, i.e. the higher the resistance of the output transistors 18, 26, the greater the gain of the circuit 1. The drain conductances of the gain transistors 42, 44, and the upper transistors 50, 70, are omitted from this equation since their transconductances are much higher than their respective drain conductances.

From this equation it can be seen that the transconductances of the gain transistors 42, 44 can be selected, with reference to the transconductances of the upper transistors 50, 70, in such a way as to significantly increase the gain of the circuit 1. It can furthermore be seen that if the transconductances of the gain transistors 42, 44 are not lower than those of the upper transistors 50, 70 then the gain will become negative.

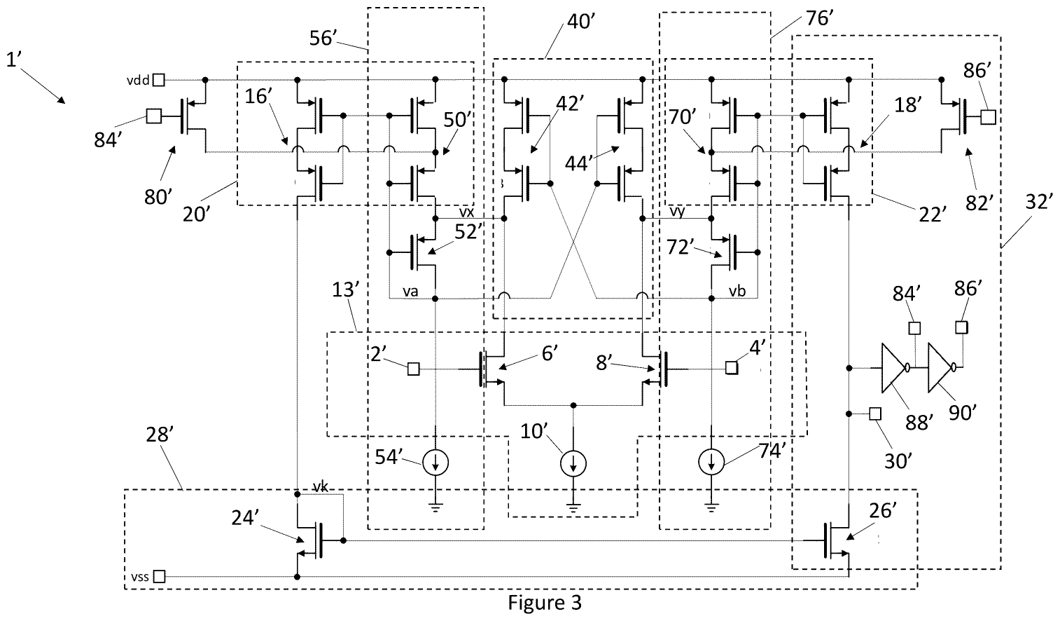

FIG. 3 illustrates an electronic comparator circuit 1′ according to a second embodiment of the present invention. This embodiment includes all the same components as the embodiment of FIG. 2, which are all labelled with like reference numerals, but followed by an apostrophe. The electronic comparator circuit 1′ further includes additional components which allow hysteresis to be achieved.

Hysteresis is a lag in the circuit activating or deactivating in response to an input. The analogue voltage inputs to the circuit will be noisy, and this noise could cause bursts on the output, during which it switches many times during a short period of time. This is undesirable as such an output is not useful. Instead it is desirable that a higher threshold for voltage difference (than zero) must be reached in order for the output voltage to switch. This helps to prevent glitching of the output signal as a result of rapid changes as described above.

In this example circuit hysteresis is achieved by additional hysteresis transistors 80′, 82′, as described below.

In this embodiment, the mirror transistor 16, the two upper transistors 50, 70, the two gain transistors 42, 44, and the output transistor 18 of the embodiment of FIG. 2 have each been split to instead be provided by respective pairs of series-connected transistors 16′, 50′, 42′, 44′, 70′, 18′.

The left-hand hysteresis transistor 80′ has its drain connected to a point between the pair of upper transistors 50′. Similarly, the right-hand hysteresis transistor 82′ has its drain connected to a point between the pair of upper transistors 70′. As a result, when one of the hysteresis transistors 80′, 82′ is conducting, it “steals” some current from its associated branch of the comparator circuit 1′, i.e. a portion of the current from the respective current source 54′, 74′ flows through the hysteresis transistor 80′, 82′, rather than through the upper-most transistor of the pair of upper transistors 50′, 70′. As a result, this reduces the current that is mirrored to the output, for the branch that has its hysteresis transistor 80′, 82′ activated. Thus, a greater increase in voltage on that branch is needed to cause the output voltage 30′ to trip to the corresponding output.

The activation of each hysteresis transistor 80′, 82′ is controlled by a respective control voltage 84′, 86′. Although not illustrated in FIG. 2, the output voltage 30, 30′ may be converted to a binary value. This is achieved in the example of FIG. 3 through the inclusion of a first inverter 88′. The first inverter 88′ is such that it both inverts the output voltage 30′ and converts it from an analog signal (albeit generally having one of two values) to a fully digital signal, by virtue of its buffering characteristics. This binary, inverted version of the voltage output 30′ is then used to control a first hysteresis transistor 80′. The control voltage 84′ for the left-hand hysteresis transistor 80′ is obtained by passing the binary output voltage 30′ through a first inverter 88′ (which also makes the signal binary, as explained above). The control voltage 86′ for the right-hand transistor 82′ is obtained by passing the control voltage 84′ for the right-hand hysteresis transistor 80′ through a further inverter 90′. Whilst the output voltage itself could be used as one of the control signals, this is not desirable since passing the output signal through an inverter will provide high gain, providing faster hysteresis, and also meaning that if only one control signal is received from an inverter, there will be an asymmetry to the circuit.

Since the control voltages 84′, 86′ are inverted with respect to each other, and the voltage output 30′ (from which they are derived) is binary, only one of the hysteresis transistors 80′, 82′ is active at any one time.

Thus, when the circuit 1′ first begins to receive a signal, one of the inputs (e.g. input 2′) will register as being higher, in a manner which switches the output 30′ to indicate that input (2′) as being higher. This will cause the hysteresis transistor 80′, 82′ associated with the other input (e.g. input 4′), i.e. with the other branch of the circuit 1′, to be activated. As a result, the current in that other branch must increase significantly (by greater than is needed in the absence of the hysteresis transistor 82′) in order to switch the output to indicate that the input 4′ is the higher input. This prevents multiple sudden switches of the output due to noise or disturbances.

It will be appreciated that this is a similar effect to the transistors used for gain, as described above, but without the cross-coupling so that hysteresis is achieved, rather than gain. This is most effective where the hysteresis transistors 80′, 82′ have greater transconductance than the upper transistors 50′, 70′. In this example, it is desirable that the hysteresis transistors 80′, 82′ short the upper transistors 50′, 70, so their transconductances will preferably be much higher than those of the upper transistors 50′, 70′.

1. An electronic comparator circuit, comprising:
an input portion, comprising a first input transistor, comprising a gate connected to a first voltage input, and a second input transistor, comprising a gate connected to a second voltage input;
an output portion, arranged to produce an output voltage dependent upon the relative values of the first voltage input and the second voltage input;
a first portion, comprising a third transistor, a fourth transistor, and a first current supply, connected in series, wherein a first terminal of the first input transistor is connected between a first terminal of the third transistor and a second terminal of the fourth transistor, such that the first terminal of the first input transistor and the first terminal of the third transistor are at the same voltage, wherein the fourth transistor is connected in a diode configuration;
a second portion, comprising a fifth transistor, a sixth transistor, and a second current supply, connected in series, wherein a first terminal of the second input transistor is connected between a first terminal of the fifth transistor and a second terminal of the sixth transistor, such that the first terminal of the second input transistor and the first terminal of the fifth transistor are at the same voltage, wherein the sixth transistor is connected in a diode configuration; and
a gain portion, comprising a seventh gain transistor and an eighth gain transistor, wherein a gate of the seventh gain transistor is cross-coupled to a gate of the fifth transistor, a gate of the eighth gain transistor is cross-coupled to a gate of the third transistor, the transconductance of the seventh gain transistor is lower than the transconductance of the third transistor and the transconductance of the eighth gain transistor is lower than the transconductance of the fifth transistor.

2. The electronic comparator circuit as claimed in claim 1, wherein the third transistor and the fourth transistor have the same aspect ratio and/or wherein the fifth transistor and the sixth transistor have the same aspect ratio.

3. The electronic comparator circuit as claimed in claim 1, wherein the voltage drop across the third transistor is approximately 50 mV and/or wherein the voltage drop across the fifth transistor is approximately 50 mV.

4. The electronic comparator circuit as claimed in claim 1, further comprising at least one hysteresis transistor, wherein the at least one hysteresis transistor is arranged to provide hysteresis of the output portion.

5. The electronic comparator circuit as claimed in claim 4, further comprising at least one inverter, arranged to invert the output voltage, and to supply this inverted output voltage to one of the at least one hysteresis transistors as a control signal.

6. The electronic comparator circuit as claimed in claim 1, further comprising a thirteenth hysteresis transistor and a fourteenth hysteresis transistor, wherein the third transistor comprises a first pair of series-connected transistors and the fifth transistor comprises a second pair of series-connected transistors, wherein a first terminal of the thirteenth hysteresis transistor is connected between the first pair of series-connected transistors and wherein a first terminal of the fourteenth hysteresis transistor is connected between the second pair of series-connected transistors.

7. The electronic comparator circuit as claimed in claim 6, further comprising a first inverter, arranged to invert the output voltage, and to apply the resulting signal to a gate of the thirteenth hysteresis transistor and a second inverter, arranged to invert the resulting signal produced by the first inverter, and to apply the further inverted signal to a gate of the fourteenth hysteresis transistor.

8. The electronic comparator circuit as claimed in claim 1, wherein at least one of the third transistor, the fourth transistor, the seventh gain transistor, and the eighth gain transistor are provided by a series-connected pair of transistors.

9. The electronic comparator circuit as claimed in claim 1, further comprising a third current supply, wherein the first input transistor and the second input transistor are connected in parallel to the third current supply.

10. The electronic comparator circuit as claimed in claim 9, wherein the third current supply supplies a current of approximately 30 nA.

11. The electronic comparator circuit as claimed in claim 1, wherein the first current supply and the second current supply approximately the same current.

12. The electronic comparator circuit as claimed in claim 11, wherein the first current supply and the second current supply each supply a current of approximately 7.5 nA.

13. The electronic comparator circuit as claimed in claim 1, wherein the first terminals are drain terminals and wherein the second terminals are source terminals.

14. The electronic comparator circuit as claimed in claim 1, wherein at least one of the third transistor, the fourth transistor, the fifth transistor, the sixth transistor, the seventh gain transistor, and/or the eighth gain transistor is a PMOS transistor.

15. The electronic comparator circuit as claimed in claim 1, wherein the first input transistor and the second input transistor are NMOS transistors.

16. The electronic comparator circuit as claimed in claim 1, further comprising a first mirror portion, arranged to mirror current from the fifth transistor to the output portion and a second mirror portion, arranged to mirror current from the third transistor to the output portion.
